(19) United States
(12) Patent Application Publication
(10) Pub. No.: US 2013/0321050 A1
(43) Pub. Date: Dec. 5, 2013

(54) DELAY-LOCKED LOOP

(71) Applicant: SK HYNIX INC., Icheon-si (KR)

(72) Inventor: Kwang Jin NA, Icheon-si (KR)

(73) Assignee: SK hynix Inc., Icheon-si (KR)

(21) Appl. No.: 13/707,689

(22) Filed: Dec. 7, 2012

(30) Foreign Application Priority Data
Jun. 1, 2012 (KR) 10-2012-0059296

(51) Int. Cl. H03L 7/08

(52) U.S. Cl. CPC H03L 7/08
USPC 327/158

(57) ABSTRACT

A delay-locked loop to control a delay amount of an external clock based on phase comparisons of a feedback clock acquired by delaying a DLL clock and the external clock and generate the DLL clock includes first and second delay units, a phase mixing unit and a slew rate control unit. The first delay unit increases the delay amount of the external clock through short and long delay elements, and generates a first delayed clock. The second delay unit increases the delay amount of the external clock through short and long delay elements, and generates a second delayed clock. The phase mixing unit mixes phases of the first and second delayed clocks. The slew rate control unit increases electrical load of the first and second delayed clocks when the delay amount of the external clock is controlled through the long delay elements of the first delay unit.

### CROSS-REFERENCES TO RELATED APPLICATION

The present application claims priority under 35 U.S.C. §119(a) to Korean application number 10-2012-0059296, filed on Jun. 1, 2012, in the Korean Intellectual Property Office, which is incorporated herein by reference in its entirety.

### BACKGROUND

1. Technical Field

The present invention generally relates to a semiconductor integrated circuit, and more particularly, to a delay-locked loop.

2. Related Art

A semiconductor device utilizes a clock synchronization system to match operation timing to ensure a quick operation with no error. If an external clock is used in the semiconductor device, clock skew is introduced by an internal circuit, which may be reflected in data to be outputted. A delay-locked loop is provided to generate a DLL clock by compensating for a model delay value (tREP) acquired by modeling the delay amount of the internal circuit of the semiconductor device, that is, a data output path. In the semiconductor device, by using the DLL clock, data may be outputted externally in synchronization with the external clock.

FIG. 1 is a block diagram of a conventional delay-locked loop.

The delay-locked loop includes a variable delay block 1, a delay modeling block 2, a phase comparison block 3, and a delay amount control block 4.

The variable delay block 1 controls the delay amount of an external clock EXTCLK in response to a delay amount select signal SEL, and generates and outputs a DLL clock DLLCLK.

The delay modeling block 2 delays the DLL clock DLLCLK by a model delay value, and generates a feedback clock FBCLK.

The phase comparison block 3 compares the phases of the feedback clock FBCLK with the external clock EXTCLK, and generates a phase detection signal PDET according to a comparison result. The phase detection signal PDET is updated with a predetermined cycle until the phases of the feedback clock FBCLK and the external clock EXTCLK become equivalent, at which time the locking of the delay-locked loop is implemented.

The delay amount control block 4 generates the delay amount select signal SEL in response to the phase detection signal PDET.

Various methods for generating the DLL clock DLLCLK by finely delaying the external clock EXTCLK have been proposed in the art. In one method, the variable delay block 1 of FIG. 1 includes a plurality of delay units 10 and 20 which delay the phase of the external clock EXTCLK by different amounts. By mixing the phases of delayed clocks DCLK1 and DCLK2 outputted from the plurality of delay units 10 and 20, through the phase mixing unit 30, the delay amount of the external clock EXTCLK may be finely controlled. FIG. 1 particularly illustrates the variable delay block 1 having two delay units, a first delay unit 10 and a second delay unit 20.

Since each of the delay units 10 and 20 includes a plurality of short delay elements SD1 to SDm and a plurality of long delay elements LD1 to LDn, delay amounts may vary. For example, initially, the delay amount of the external clock EXTCLK may be increased by a relatively short margin through the short delay elements SD1 to SDm, and, if locking is not implemented after the lapse of a predetermined time, the delay amount of the external clock EXTCLK may be relatively further increased through the long delay elements LD1 to LDn. When the external clock EXTCLK with a relatively high frequency is applied, a delay amount may be controlled using only the short delay elements SD1 to SDm, and, when the external clock EXTCLK with a relatively low frequency is applied, a delay amount may be controlled using the long delay elements LD1 to LDn together with the short delay elements SD1 to SDm. Accordingly, for a clock with relatively low frequency and a relatively large delay amount for locking, a delay amount may be quickly controlled.

In order to control the delay amounts of the first delay unit 10 and the second delay unit 20, the delay amount control block 4 generates a first delay amount select signal SEL1 (not shown) to be applied to the first delay unit 10 and a second delay amount select signal SEL2 (not shown) to be applied to the second delay unit 20, which are collectively labeled as the delay amount select signal SEL. Each of the first and second delay amount select signals SEL1 and SEL2 includes a plurality of short delay select signals for selecting the plurality of short delay elements SD1 to SDm and a plurality of long delay select signals for selecting the plurality of long delay elements LD1 to LDn. The delay amount control block 4 activates the first and second delay amount select signals SEL1 and SEL2 in such a manner that the first delayed clock DCLK1 and the second delayed clock DCLK2 have a predetermined phase difference, such as the first delayed clock DCLK1 being delayed by one more delay element than the second delayed clock DCLK2.

The phase mixing unit 30 mixes the phases of the first delayed clock DCLK1 and the second delayed clock DCLK2 according to a preset weight, and generates the DLL clock DLLCLK. When the external clock EXTCLK has a relatively high frequency and thus is delayed by only the short delay elements SD1 to SDm, since the phase difference between the first and second delayed clocks DCLK1 and DCLK2 inputted into the phase mixing unit 30 is relatively small, linearity in the operation of the phase mixing unit 30 is ensured. Conversely, when the external clock EXTCLK has a relatively low frequency and thus is delayed by the long delay elements LD1 to LDn together with the short delay elements SD1 to SDm, since the phase difference between the first and second delayed clocks DCLK1 and DCLK2 inputted into the phase mixing unit 30 is relatively large, achieving secure linearity in the operation of the phase mixing unit 30 is difficult.

FIGS. 2a and 2b are waveform diagrams showing the operation of the phase mixing unit 30.

FIG. 2a is a waveform diagram showing the operation of the phase mixing unit 30 when the external clock EXTCLK has a relatively high frequency. Because the phase difference between the two input clocks, the first and second delayed clocks DCLK1 and DCLK2, is relatively small, the phases of the first and second delayed clocks DCLK1 and DCLK2 may be mixed according to a preset weight.

Conversely, FIG. 2b is a waveform diagram showing the operation of the phase mixing unit 30 when the external clock EXTCLK has a relatively low frequency. Because the phase difference between two input clocks, the first and second delayed clocks DCLK1 and DCLK2, is relatively large, the phases of the first and second delayed clocks DCLK1 and DCLK2 may not be mixed according to a preset weight, and a nonlinear characteristic may result.

When the external clock EXTCLK has a relatively low frequency, reliability and efficiency of the operation of the entire circuit of the delay-locked loop are likely to deteriorate due to the nonlinear characteristic of the phase mixing unit 30.

### SUMMARY

In an embodiment, a delay-locked loop configured to control a delay amount of an external clock based on phase comparisons of a feedback clock acquired by delaying a DLL clock by a model delay value with the external clock, and generate the DLL clock includes: a first delay unit configured to increase the delay amount of the external clock through a plurality of short delay elements and a plurality of long delay elements which are connected in series, and generate a first delayed clock; a second delay unit configured to increase the delay amount of the external clock through a plurality of short delay elements and a plurality of long delay elements which are connected in series, and generate a second delayed clock; a phase mixing unit configured to mix phases of the first delayed clock and the second delayed clock, and generate the DLL clock; and a slew rate control unit configured to increase electrical load of the first delayed clock and the second delayed clock when the delay amount of the external clock is controlled through the long delay elements included in the first delay unit.

In another embodiment, a delay-locked loop includes: a variable delay block configured to control a delay amount of an external clock by first and second delay amount select signals, and output a DLL clock; a delay modeling block configured to delay the DLL clock by a model delay value, and generate a feedback clock; a phase comparison block configured to compare phases of the feedback clock and the external clock, and generate a phase detection signal based on the phase comparisons; and a delay amount control block configured to generate the first and second delay amount select signals in response to the phase detection signal. The variable delay block further includes: a first delay unit configured to increase the delay amount of the external clock through a plurality of short delay elements and a plurality of long delay elements which are connected in series, in response to the first delay amount select signal, and generate a first delayed clock; a second delay unit configured to increase the delay amount of the external clock through a plurality of short delay elements and a plurality of long delay elements which are connected in series, in response to the second delay amount select signal, and generate a second delayed clock; a phase mixing unit configured to mix phases of the first delayed clock and the second delayed clock, and generate the DLL clock; and a slew rate control unit configured to increase electrical load of the first delayed clock and the second delayed clock in response to the first delay amount select signal.

### BRIEF DESCRIPTION OF THE DRAWINGS

Features, aspects, and embodiments are described in conjunction with the attached drawings, in which:

FIG. 1 is a block diagram of a conventional delay-locked loop;

FIGS. 2a and 2b are waveform diagrams showing the operation of the phase mixing unit of FIG. 1;

FIG. 3 is a block diagram of a delay-locked loop in accordance with an embodiment;

FIG. 4 is a circuit diagram showing the switching control section of FIG. 3; and

FIG. 5 is a waveform diagram showing the operation of the phase mixing unit of FIG. 3.

### DETAILED DESCRIPTION

Hereinafter, a delay-locked loop according to the present invention will be described below with reference to the accompanying drawings through various embodiments.

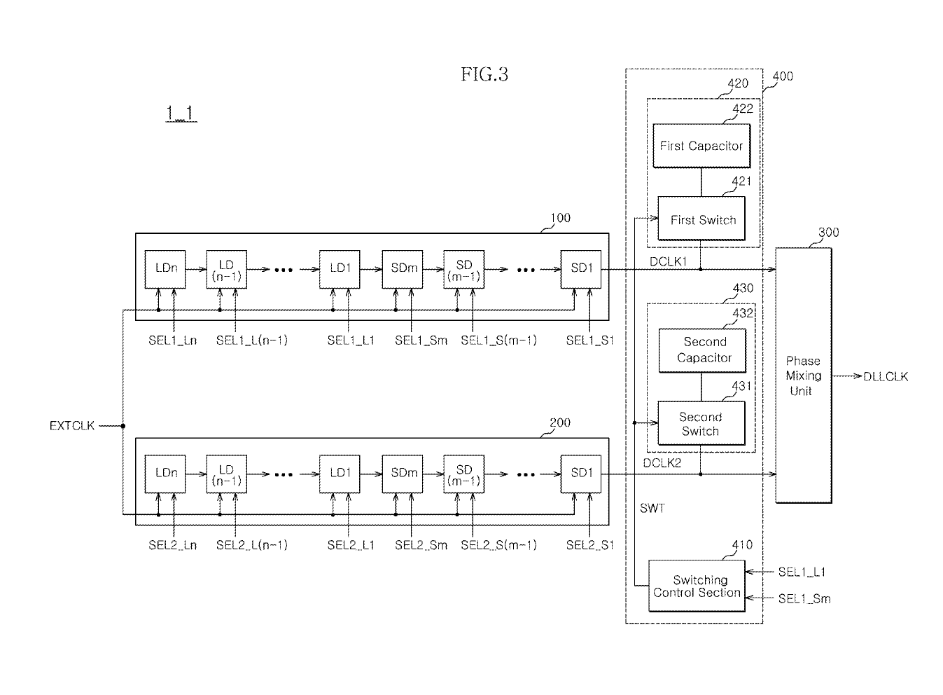

FIG. 3 is a block diagram of a delay-locked loop in accordance with an embodiment.

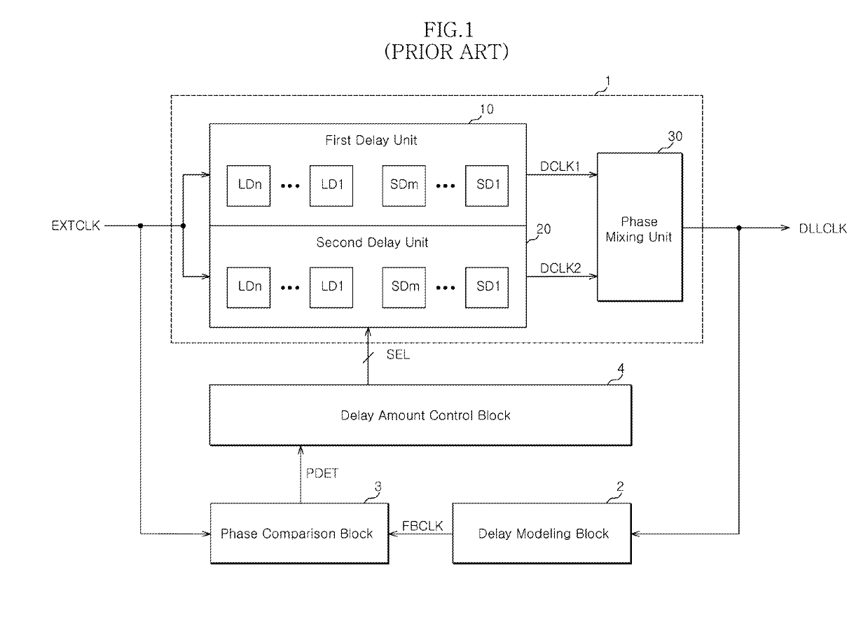

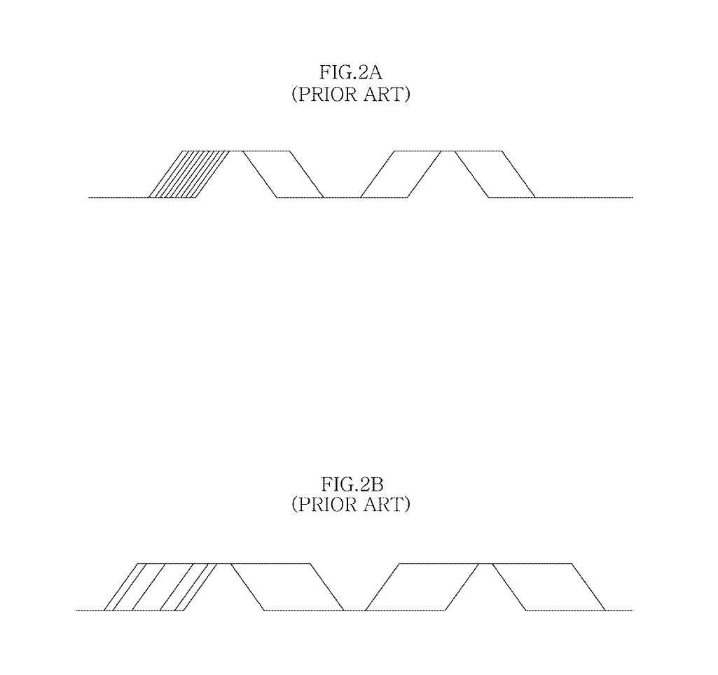

A delay-locked loop in accordance with an embodiment includes a delay modeling block 2, a phase comparison block 3 and a delay amount control block 4 which are configured in the same way as described above with reference to FIG. 1, and a variable delay block 1_1 which has an improved configuration than that of the variable delay block of FIG. 1. FIG. 3 shows a detailed block diagram of the improved variable delay block 1_1.

The variable delay block 1_1 of FIG. 3 includes a first delay unit 100, a second delay unit 200, a phase mixing unit 300, and a slew rate control unit 400.

The first delay unit 100 includes a plurality of short delay elements SD1 to SDm and a plurality of long delay elements LD1 to LDn which are configured to control delay amounts in response to first delay amount select signals SEL1_S1 to SEL1_Sm and SEL1_L1 to SEL1_Ln. The first delay amount select signals SEL1_S1 to SEL1_Sm and SEL1_L1 to SEL1_Ln include a plurality of first short delay select signals SEL1_S1 to SEL1_Sm and a plurality of first long delay select signals SEL1_L1 to SEL1_Ln. The plurality of first short delay select signals SEL1_S1 to SEL1_Sm control selection of the plurality of short delay elements SD1 to SDm, and the plurality of first long delay select signals SEL1_L1 to SEL1_Ln control selection of the plurality of long delay elements LD1 to LDn. The plurality of first short delay select signals SEL1_S1 to SEL1_Sm and the plurality of first long delay select signals SEL1_L1 to SEL1_Ln are sequentially activated until the delay-locked loop is locked. The delay element which is selected by the activated delay select signal receives an external clock(EXTCLK) to delay. The delay elements positioned behind the selected delay element sequentially delay an output of the selected delay element.

The first delay unit 100 is configured to sequentially increase the delay amount of an external clock EXTCLK through the plurality of short delay elements SD1 to SDm and the plurality of long delay elements LD1 to LDn which are connected in series, and generate a first delayed clock DCLK1.

The second delay unit 200 includes a plurality of short delay elements SD1 to SDm and a plurality of long delay elements LD1 to LDn which are configured to control delay amounts in response to second delay amount select signals SEL2_S1 to SEL2_Sm and

SEL2_L1 to SEL2_Ln. The second delay amount select signals SEL2_S1 to SEL2_Sm and SEL2_L1 to SEL2_Ln include a plurality of second short delay select signals SEL2_S1 to SEL2_Sm and a plurality of second long delay select signals SEL2_L1 to SEL2_Ln, respectively. The plurality of second short delay select signals

SEL2_S1 to SEL2_Sm control selection of the plurality of short delay elements SD1 to SDm, and the plurality of second long delay select signals SEL2_L1 to SEL2_Ln control selection of the plurality of long delay elements LD1 to LDn. The plurality of second short delay select signals SEL2_S1 to SEL2_Sm and the plurality of second long delay select signals SEL2_L1 to SEL2_Ln are sequentially activated until the delay-locked loop is locked.

The second delay unit 200 is configured to sequentially increase the delay amount of the external clock EXTCLK through the plurality of short delay elements SD1 to SDm and the plurality of long delay elements LD1 to LDn which are connected in series, and generate a second delayed clock DCLK2.

The first and second delay units 100 and 200 may increase initially the delay amount of the external clock EXTCLK by a relatively short amount through the short delay elements SD1 to SDm, and may increase the delay amount of the external clock EXTCLK by a relatively long amount through the long delay elements LD1 to LDn when locking is not implemented even after the lapse of a predetermined time. When the external clock EXTCLK has a relatively high frequency, the delay amount may be controlled using only the short delay elements SD1 to SDm, and when the external clock EXTCLK has a relatively low frequency, the delay amount may be controlled using the long delay elements LD1 to LDn together with the short delay elements SD1 to SDm.

The first delay amount select signals SEL1_S1 to SEL1_Sm and SEL1_L1 to SEL1_Ln and the second delay amount select signals SEL2_S1 to SEL2_Sm and SEL2_L1 to SEL2_Ln are activated in such a manner that the first delayed clock DCLK1 and the second delayed clock DCLK2 have a predetermined phase difference, such as the first delayed clock DCLK1 being delayed by one more delay element than the second delayed clock DCLK2.

The phase mixing unit 300 is configured to mix the phases of the first delayed clock DCLK1 and the second delayed clock DCLK2 according to a preset weight, and generate a DLL clock DLLCLK.

The slew rate control unit 400 is configured to increase the electrical load of the first delayed clock DCLK1 and the second delayed clock DCLK2 in response to the first delay amount select signals SEL1_Sm and SEL1_L1.

The slew rate control unit 400 includes a switching control section 410, a first slew rate control section 420, and a second slew rate control section 430.

The switching control section 410 is configured to receive the SEL1_L1 and SEL1_Sm, and generate a switching signal SWT.

SEL1_L1 is activated earliest among all first long delay amount select signals SEL1_L1 to SEL1_Ln when increasing the delay amounts. SEL1_Sm is activated earliest among all short delay amount select signals SEL1_S1 to SEL1_Sm when decreasing the delay amounts after SEL1_L1 is activated. The switching control section 410 activates the switching signal SWT in response to SEL1_L1 and deactivates the switching signal SWT in response to SEL1_Sm .

The first slew rate control section 420 is configured to increase the electrical load of the first delayed clock DCLK1 in response to the switching signal SWT. The rising and falling slopes of the first delayed clock DCLK1 become gentle.

The first slew rate control section 420 includes a first capacitor 422 and a first switch 421 which connects the first capacitor 422 to the output terminal of the first delay unit 100 in response to the activated switching signal SWT.

The second slew rate control section 430 is configured to increase the electrical load of the second delayed clock DCLK2 in response to the switching signal SWT. The rising and falling slopes of the second delayed clock DCLK2 become gentle.

The second slew rate control section 430 includes a second capacitor 432 and a second switch 431 which connects the second capacitor 432 to the output terminal of the second delay unit 200 in response to the activated switching signal SWT.

As a consequence, the variable delay block 1_1 according to an embodiment increases the electrical load of the first delayed clock DCLK1 and the second delayed clock DCLK2 when the delay amount of the external clock EXTCLK is controlled through the long delay elements LD1 to LDn included in the first delay unit 100.

The phase mixing unit 300 operates in a more linear fashion when mixing the phases of two clocks that have gentle slopes than when mixing the phases of two clocks that have steep slopes. If the slope of a clock becomes more gentle as the electrical load of the first and second delayed clocks DCLK1 and DCLK2 increases according to an embodiment, linearity may be more secured when the phase mixing unit 300 mixes the phases of two clocks that have a large phase difference.

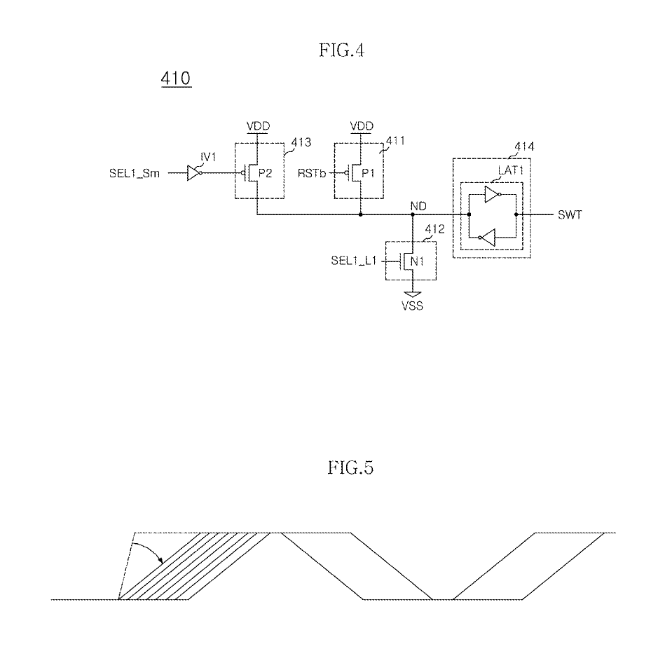

FIG. 4 is a circuit diagram showing in detail an embodiment of the switching control section 410.

The switching control section 410 includes an initialization part 411, a switching signal activation part 412, a switching signal deactivation part 413, and an output part 414.

The initialization part 411 is configured to provide an external voltage VDD to a node ND when an activated reset signal RSTb is initially applied. Initially, a deactivated switching signal SWT is generated and set at a low level.

The initialization part 411 includes a first PMOS transistor P1 which applies the external voltage VDD to the node ND in response to the reset signal RSTb.

The switching signal activation part 412 is configured to discharge the node ND to a ground voltage VSS in response to SEL1_L1, which is activated earliest among the plurality of first long delay select signals SEL1_L1 to SEL1_Ln when increasing the delay amounts. If SEL1_L1 is activated and inputted, the switching signal SWT is activated to a high level.

The switching signal activation part 412 includes a first NMOS transistor N1 which connects the node ND to the ground voltage VSS in response to SEL1_L1.

The switching signal deactivation part 413 is configured to provide the external voltage VDD to the node ND in response to the SEL1_Sm, which is activated earliest among the plurality of first short delay select signals SEL1_S1 to SEL1_Sm when decreasing the delay amounts after SEL1_L1 is activated. If SEL1_Sm is activated and inputted, the switching signal SWT is deactivated to the low level.

The switching signal deactivation part 413 includes a second PMOS transistor P2 which provides the external voltage VDD to the node ND in response to SEL1_Sm.

The output part 414 is configured to latch and buffer the voltage level of the node ND and output the switching signal SWT.

The output part 414 includes a first latch LAT1 which is connected with the node ND.

Accordingly, the switching control section 410 activates the switching signal SWT when the delay amount of the external clock

EXTCLK is controlled through the long delay elements LD1 to LDn included in the first delay unit 100. Conversely, the switching control section 410 deactivates the switching control signal SWT when the delay amount of the external clock EXTCLK is controlled through only the short delay elements SD1 to SDm included in the first delay unit 100.

In the variable delay block 1_1 in accordance with an embodiment, when the external clock EXTCLK is recognized as a relatively low frequency clock, that is, when the delay amount of the external clock EXTCLK is controlled through the long delay elements LD1 to LDn, as the electrical load of the first delayed clock DCLK1 and the second delayed clock DCLK2 increases, the phase mixing unit 300 may perform an operation in a linear manner.

FIG. 5 is a waveform diagram showing the operation of the phase mixing unit 300 according to an embodiment in a low frequency environment.

FIG. 5 shows a situation where the first and second delayed clocks DCLK1 and DCLK2 are mixed. Because the delay amount of the external clock EXTCLK is controlled through the long delay elements LD1 to LDn included in the first delay unit 100, the electrical load of the first and second delayed clocks DCLK1 and DCLK2 increases, and the slope of a clock becomes gentle. Hence, the phase mixing unit 300 may mix two clocks in a more linear manner than when the first and second delayed clocks DCLK1 and DCLK2 have steep slopes.

While certain embodiments have been described above, it will be understood to those skilled in the art that the embodiments described are by way of example only. Accordingly, the delay-locked loop described herein should not be limited based on the described embodiments. Rather, the delay-locked loop described herein should only be limited in light of the claims that follow when taken in conjunction with the above description and accompanying drawings.

1. A delay-locked loop configured to control a delay amount of an external clock based on phase comparisons of a feedback clock acquired by delaying a DLL clock by a model delay value with the external clock, and generate the DLL clock, the delay-locked loop comprising:
a first delay unit configured to vary the delay amount of the external clock in response to a first delay amount select signals and generate a first delayed clock;
a second delay unit configured to vary the delay amount of the external clock in response to a second delay amount select signals and generate a second delayed clock;
a slew rate control unit configured to vary electrical load of the first delayed clock and the second delayed clock in response to a part of the first delay amount select signals; and
a phase mixing unit configured to mix phases of the first delayed clock and the second delayed clock varied their electrical loads through the slew rate control unit, and generate the DLL clock.

2. The delay-locked loop according to claim 1, wherein the first delayed clock and the second delayed clock have a predetermined phase difference.

3. The delay-locked loop according to claim 1, wherein the first and second delay units control the delay amount of the external clock until the phases of the feedback clock and the external clock become the same with each other.

4. The delay-locked loop according to claim 1, wherein the slew rate control unit comprises:
a first slew rate control section including a first capacitor which is connected to an output terminal of the first delay unit.

5. The delay-locked loop according to claim 4, wherein the first slew rate control section further includes a first switch which connects the first capacitor to the output terminal of the first delay unit.

6. The delay-locked loop according to claim 4, wherein the slew rate control unit further comprises:
a second slew rate control section including a second capacitor which is connected to an output terminal of the second delay unit.

7. The delay-locked loop according to claim 6, wherein the second slew rate control section further includes a second switch which connects the second capacitor to the output terminal of the second delay unit.

8. A delay-locked loop comprising:
a variable delay block configured to control a delay amount of an external clock by first and second delay amount select signals, and output a DLL clock;
a delay modeling block configured to delay the DLL clock by a model delay value, and generate a feedback clock;
a phase comparison block configured to compare phases of the feedback clock with the external clock, and generate a phase detection signal according to a comparison result; and
a delay amount control block configured to generate the first and second delay amount select signals in response to the phase detection signal,
wherein the variable delay block comprises:
a first delay unit configured to vary the delay amount of the external clock in response to the first delay amount select signals, and generate a first delayed clock;
a second delay unit configured to vary the delay amount of the external clock in response to the second delay amount select signals, and generate a second delayed clock;
a slew rate control unit configured to vary electrical load of the first delayed clock and the second delayed clock in response to a part of the first delay amount select signals; and
a phase mixing unit configured to mix phases of the first delayed clock and the second delayed clock varied their electrical loads through the slew rate control unit, and generate the DLL clock.

9. The delay-locked loop according to claim 8, wherein the delay amount control block activates the first and second delay amount select signals such that the first delayed clock and the second delayed clock have a predetermined phase difference.

10. The delay-locked loop according to claim 9,
wherein the first delay amount select signals comprises a plurality of first short delay select signals and a plurality of first long delay select signals, and
wherein the second delay amount select signals comprises a plurality of second short delay select signals and a plurality of second long delay select signals.

11. The delay-locked loop according to claim 10,
wherein the delay amount control block sequentially activates the plurality of first short delay select signals and then sequentially activates the plurality of first long delay select signals, in response to the phase detection signal, and
wherein the delay amount control block sequentially activates the plurality of second short delay select signals and then sequentially activates the plurality of second long delay select signals, in response to the phase detection signal.

12. The delay-locked loop according to claim 11, wherein the slew rate control unit comprises:
a switching control section configured to receive a first long delay select signal which is activated earliest among the plurality of first long delay select signals when increasing delay amounts and a first short delay select signal which is activated earliest among the plurality of first short delay select signals when decreasing delay amounts after the first long delay select signal is activated, and generate a switching signal;
a first slew rate control section configured to increase electrical load of the first delayed clock in response to the switching signal; and
a second slew rate control section configured to increase electrical load of the second delayed clock in response to the switching signal.

13. The delay-locked loop according to claim 12,
wherein the switching control section activates the switching signal in response to the first long delay select signal which is activated earliest among the plurality of first long delay select signals when increasing delay amounts, and
wherein the switching control section deactivates the switching signal in response to the first short delay select signal which is activated earliest among the plurality of first short delay select signals when decreasing delay amounts after the first long delay select signal is activated.

14. The delay-locked loop according to claim 12, wherein the first slew rate control section comprises a first capacitor which is connected to an output terminal of the first delay unit when the switching signal is activated.

15. The delay-locked loop according to claim 14, wherein the first slew rate control section further includes a first switch which connects the first capacitor to the output terminal of the first delay unit.

16. The delay-locked loop according to claim 12, wherein the second slew rate control section comprises a second capacitor which is connected to an output terminal of the second delay unit when the switching signal is activated.

17. The delay-locked loop according to claim 16, wherein the second slew rate control section further includes a second switch which connects the second capacitor to the output terminal of the second delay unit.

18. The delay-locked loop according to claim 1, wherein the slew rate control unit is configured to vary the electrical load of the first delayed clock and the second delayed clock in response to a signal activated earliest among the first delay amount select signals.

19. The delay-locked loop according to claim 8, wherein the slew rate control unit is configured to vary the electrical load of the first delayed clock and the second delayed clock in response to a signal activated earliest among the first delay amount select signals.
